(19) United States
(12) Patent Application Publication
(10) Pub. No.: US 2024/0049612 A1
(43) Pub. Date: Feb. 8, 2024

(54) RESISTIVE RANDOM ACCESS MEMORY AND MANUFACTURING METHOD THEREOF

(71) Applicant: Winbond Electronics Corp., Taichung City (TW)

(72) Inventors: Po-Yen HSU, Taichung City (TW); Bo-Lun WU, Taichung City (TW)

(21) Appl. No.: 18/340,597

(22) Filed: Jun. 23, 2023

(30) Foreign Application Priority Data
Aug. 8, 2022 (TW) 111129685

(51) Int. Cl. H10N 70/00; H10B 63/00

(52) U.S. Cl. CPC H10N 70/841; H10B 63/80; H10N 70/061

(57) ABSTRACT

A resistive random access memory (RRAM) and its manufacturing method are provided. The RRAM includes bottom contact structures formed in a substrate, memory cells formed on the substrate, and an insulating structure formed between adjacent memory cells. The memory cell includes a bottom electrode layer, two L-shaped resistance switching layers, oxygen ion diffusion barrier layers, and a top electrode layer. The bottom electrode layer is formed on one of the bottom contact structures. The L-shaped resistance switching layer has a horizontal portion and a vertical portion, and is formed on the bottom electrode layer. The oxygen ion diffusion barrier layers are formed on the inner and outer sidewalls of the vertical portion of the L-shaped resistance switching layers. The L-shaped resistance switching layers are between the top electrode layer and the bottom electrode layer.

### CROSS REFERENCE TO RELATED APPLICATIONS

This application claims priority of Taiwan Patent Application No. 111129685, filed on Aug. 8, 2022, the entirety of which is incorporated by reference herein.

### BACKGROUND OF THE INVENTION

### Field of the Invention

The present invention relates to a memory device, and, in particular, to a resistive random access memory and a manufacturing method thereof.

### Description of the Related Art

In a conventional resistive random access memory (RRAM), the array area of the chip includes a plurality of memory cells, and each memory cell includes a patterned bottom electrode layer, a resistance switching layer, and a top electrode layer. When a forming voltage or a writing voltage is applied to the memory cell, the oxygen ions are driven by the voltage and leave the resistance switching layer. The equivalent positive oxygen vacancies remaining in the resistance switching layer form conductive paths (or conductive filaments), which in turn convert the resistance switching layer from a high resistance state (HRS) to a low resistance state (LRS). When an erase voltage is applied, the oxygen ions return to the resistance switching layer and combine with the equivalent positive oxygen vacancies. Therefore, the conductive path disappears, and the resistance switching layer is converted from LRS to HRS.

When the writing voltage is applied to convert the resistance switching layer into LRS, oxygen ions usually move toward the oxygen ion storage layer above the resistance switching layer. However, in a conventional RRAM, some oxygen ions may move horizontally and remain in the resistance switching layer. If these oxygen ions remaining in the resistance switching layer obtain energy from a high-temperature environment (e.g., the high-temperature environment of the durability test), then they will recombine with oxygen vacancies in adjacent conductive paths. As a result, the resistance value of the low-resistance state will be increased. That is, a degradation of the low-resistance state (LRS degrade) occurs.

On the other hand, when the resistance switching layer is in HRS, if oxygen ions in the resistance switching layer obtain energy from a high-temperature environment (e.g., the high-temperature environment of the durability test), then some oxygen ions may diffuse in the horizontal direction and leave oxygen vacancies to form conductive paths. As a result, the resistance value of the high resistance state will be reduced. That is, a degradation of high resistance state (HRS degrade) occurs. When the LRS degrade or the HRS degrade occur, the yield and reliability of the memory device will be reduced.

Moreover, in a conventional RRAM, every time voltage is applied, the conductive paths in the resistance switching layer are formed randomly and cannot be controlled. In addition, when voltage is applied, the resistance values of the resistance switching layers of the memory cells in different positions are also different. Therefore, the reliability and performance uniformity of the memory device are not satisfactory.

### BRIEF SUMMARY OF THE INVENTION

An embodiment of the present invention provides an RRAM and a manufacturing method thereof, which may increase the yield and reliability of the memory device and improve the uniformity of reliability and performance.

An embodiment of the present invention provides an RRAM. The RRAM includes bottom contact structures formed in a substrate and memory cells formed on the substrate. Each memory cell includes a bottom electrode layer formed on one of the bottom contact structures and two L-shaped resistance switching layers formed on the bottom electrode layer. Each L-shaped resistance switching layer has a horizontal portion and a vertical portion. Each memory cell also includes oxygen ion diffusion barrier layers formed on inner and outer sidewalls of the vertical portion of each L-shaped resistance switching layers. Each memory cell further includes a top electrode layer. The L-shaped resistance switching layers and the oxygen ion diffusion barrier layers are between the top electrode layer and the bottom electrode layer. The RRAM also includes an insulating structure formed between adjacent two of the memory cells.

An embodiment of the present invention provides manufacturing method of a resistive random access memory. The method includes the following steps. Bottom contact structures are formed in a substrate. A bottom electrode material is formed on the substrate. A sacrificial pattern layer is formed on the bottom electrode material, wherein the sacrificial pattern layer includes first openings. A resistance switching material is conformally formed on the sacrificial pattern layer. A first oxygen ion diffusion barrier material is conformally formed on the resistance switching material. A planarization process is performed to make sure a top surface of the first oxygen ion diffusion barrier material, a top surface of the resistance switching material and a top surface of the sacrificial pattern layer are coplanar. The sacrificial pattern layer is removed to form second openings, wherein the second openings expose sidewalls of the resistance switching material. A second oxygen ion diffusion barrier layer is formed on the sidewalls of the resistance switching material. A top electrode material is formed on the resistance switching material, the first oxygen ion diffusion barrier material, and the second oxygen ion diffusion barrier layer. A patterning process is performed to form an opening of insulating structure through the bottom electrode material, the resistance switching material, the first oxygen ion diffusion barrier material, and the top electrode material to define memory cells on the substrate. An insulating structure is formed in the opening of the insulating structure.

In the RRAM provided by the embodiments of the present invention, a resistance switching layer having a specific shape (e.g., L-shaped and U-shaped) and size is formed. In this way, the position and shape of the conductive paths may be effectively controlled, thereby improving the uniformity of reliability and performance. Furthermore, in the RRAM provided by the embodiments of the present invention, oxygen ion diffusion barrier layers are provided on the inner and outer sidewalls of the vertical portion of the resistance switching layer. The oxygen ion diffusion barrier layer may confine the horizontal movement of oxygen ions in the resistance switching layer, and may also prevent oxygen ions from the insulating layer from entering the resistance switching layer to affect the number and size of conductive paths. In other words, LRS degrade or HRS degrade may be prevented, and yield and reliability may be improved.

### BRIEF DESCRIPTION OF THE DRAWINGS

The present invention can be more fully understood by reading the subsequent detailed description and examples with references made to the accompanying drawings, wherein:

FIGS. 1A-1G are schematic cross-sectional views corresponding to steps of manufacturing an RRAM according to some embodiments of the present invention.

FIG. 2 is a schematic cross-sectional view of an RRAM according to some other embodiments of the present invention.

FIG. 3A and FIG. 3B are schematic cross-sectional views corresponding to steps of manufacturing an RRAM according to some other embodiments of the present invention.

FIG. 4 is a schematic cross-sectional view of an RRAM according to some other embodiments of the present invention.

### DETAILED DESCRIPTION OF THE INVENTION

To make the above-mentioned and other objects, features, and advantages of the present invention more clearly, preferred embodiments are given below, and are described in detail as follows with the accompanying drawings. Furthermore, repeated reference numerals and/or letters may be used in different examples of the present invention. These repeated reference numerals and/or letters are used for the purpose of simplicity and clarity, and are not used to limit the relationship between the various embodiments and/or the configurations discussed.

Here, the terms “about,” “approximately” typically mean +/−20% of the stated value, more typically +/−10% of the stated value, more typically +/−5% of the stated value. The stated value herein is an approximate value. That is, when there is no specific description of the terms “about,” “approximately”, the stated value includes the meaning of “about,” “approximately”. In this specification, “X is equal to or close to Y” means that the absolute value of the difference between the two is within 5.0% of the larger one.

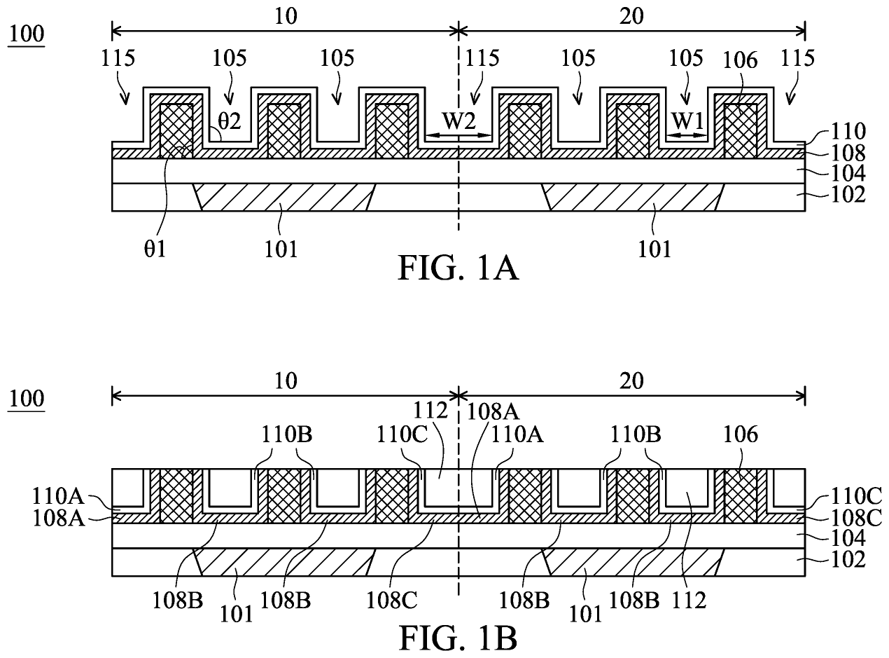

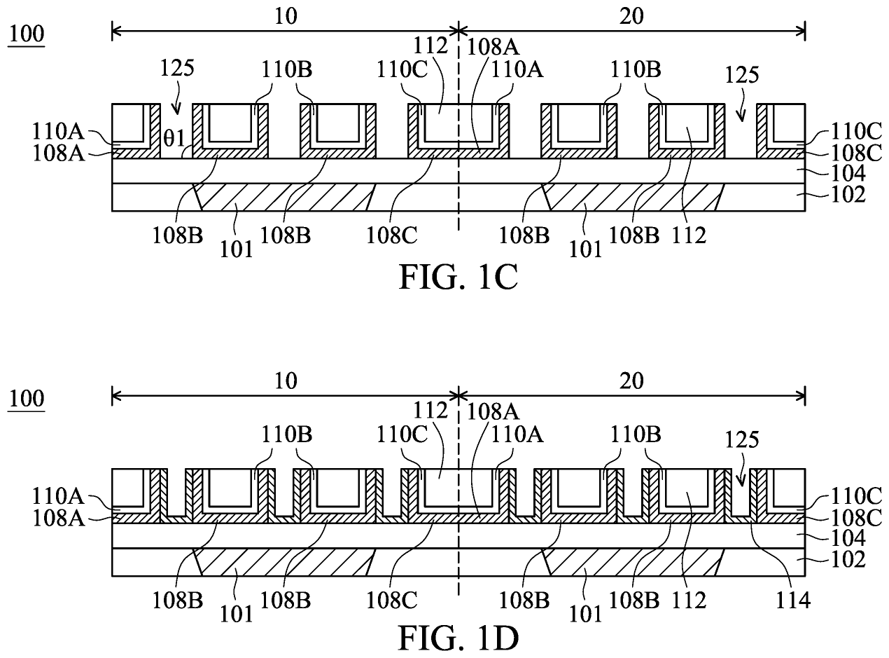

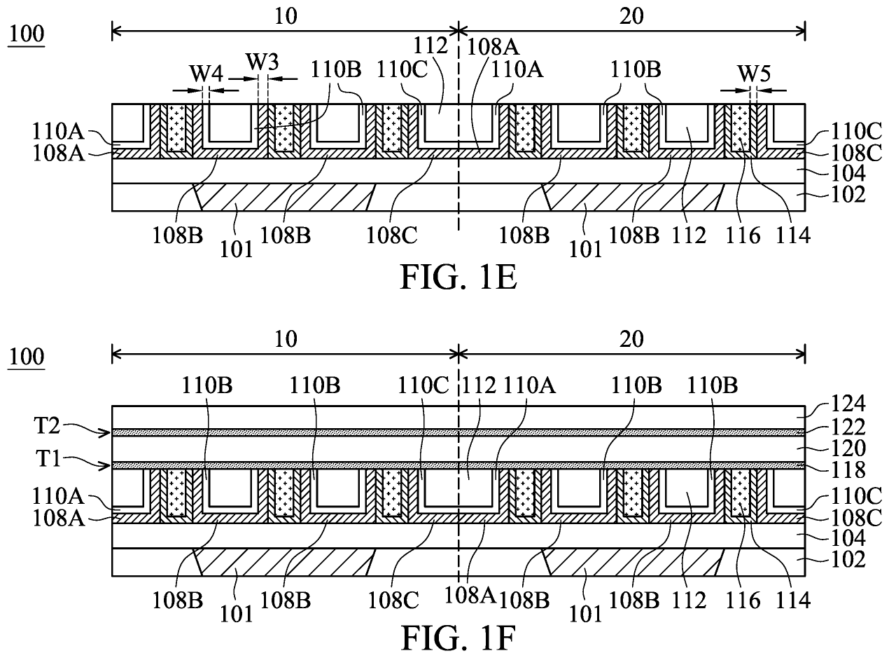

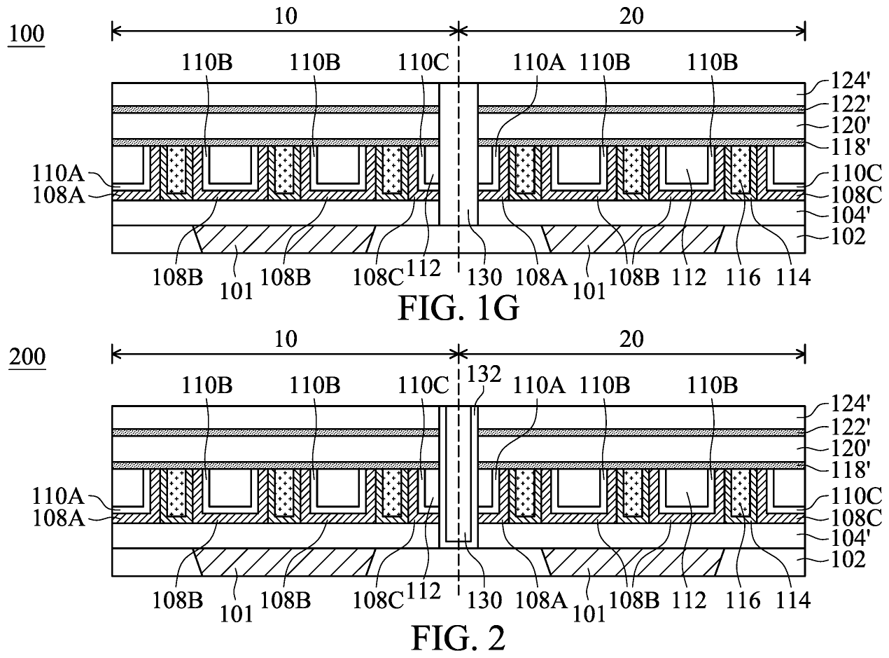

FIGS. 1A-1G are schematic cross-sectional views corresponding to steps of manufacturing a resistive random access memory (RRAM) according to some embodiments of the present invention. Referring to FIG. 1A, bottom contact structures 101 are formed in the substrate 102. The substrate 102 includes a first region 10 and a second region 20, and has a bottom contact structure 101 in each of the first region 10 and the second region 20. In FIGS. 1A to 1G, the interface of the first region 10 and the second region 20 is marked with a dotted line.

The material of the substrate 102 may include bulk semiconductor substrates (e.g., silicon substrates), compound semiconductor substrates (e.g., group IIIA-VA semiconductor substrates), silicon on insulator (SOI) substrates, and the like. The substrate 102 may be a doped or undoped semiconductor substrate. In some embodiments, the substrate 102 is a silicon substrate. In some embodiments, the bottom contact structure 101 is a single-layer structure formed of a conductive layer, and the conductive layer includes tungsten, aluminum, copper, silver, other suitable metals, or a combination thereof. In other embodiments, the bottom contact structure 101 is a double-layer structure and includes a liner layer and a conductive layer. The liner layer may improve the adhesion between the conductive layer and the substrate 102, and may prevent metal atoms from diffusing into the substrate 102. The material of the liner layer may include titanium, titanium nitride, tungsten nitride, tantalum or tantalum nitride, other suitable conductive materials, or a combination thereof.

Next, a bottom electrode material 104 is formed on the substrate 102. The bottom electrode material 104 may include titanium, tantalum, titanium nitride, tantalum nitride, other suitable conductive materials, or a combination thereof. Next, a sacrificial pattern layer 106 is formed on the bottom electrode material 104. The sacrificial pattern layer 106 includes first openings 105 and second openings 115. The first openings 105 and the second openings 115 expose the top surface of the bottom electrode material 104. In this embodiment, the first opening 105 has a first width W1, and the second opening 115 has a second width W2 greater than the first width W1. The sacrificial pattern layer 106 may include suitable materials such as nitride, oxide, carbide, oxynitride, or polysilicon. In some embodiments, the sacrificial pattern layer 106 is silicon nitride.

Next, the resistance switching material 108 is conformally formed on the sacrificial pattern layer 106. The resistance switching material 108 may determine the resistance state of the memory cell. The resistance switching material 108 may include a transition metal oxide, such as aluminum oxide (AlₓO_{y}), titanium oxide (TiₓO_{y}), nickel oxide (NiₓO_{y}), tantalum oxide (TaₓO_{y}), hafnium oxide (HfₓO_{y}), or zirconium oxide (ZrₓO_{y}). The resistive switching material 108 may be formed by chemical vapor deposition, atomic layer deposition, or any other suitable deposition process. In some embodiments, the resistance switching material 108 is hafnium oxide (HfO₂) formed by atomic layer deposition.

Next, a first oxygen ion diffusion barrier material 110 is conformally formed on the resistance switching material 108. The first oxygen ion diffusion barrier material 110 may be used to block oxygen ions, so that the movement of the oxygen ions becomes more difficult. Therefore, the horizontal movement of oxygen ions may be reduced or avoided. That is, the diffusion of oxygen ions from the resistance switching material 108 into the subsequently formed first insulating layer 112 (shown in FIG. 1B) may be prevented, and the diffusion of oxygen ions from the subsequently formed first insulating layer 112 into the resistance switching material 108 may be prevented. In order to block the horizontal movement of oxygen ions, the first oxygen ion diffusion barrier material 110 may be different from the resistance switching material 108. The first oxygen ion diffusion barrier material 110 may include aluminum oxide (AlₓO_{y}), titanium oxynitride (TiₓO_{y}N_{z}), titanium oxide (TiₓO_{y}), tantalum oxide (TaₓO_{y}), hafnium oxide (HfₓO_{y}), nickel oxide (NiₓO_{y}), zirconium oxide (ZrₓO_{y}) or a combination thereof. In some embodiments, the first oxygen ion diffusion barrier material 110 is titanium oxynitride (TiON). The first oxygen ion diffusion barrier material 110 may be formed by chemical vapor deposition, atomic layer deposition, or any other suitable deposition process. In some embodiments, the first oxygen ion diffusion barrier material 110 is formed by atomic layer deposition of aluminum oxide (Al₂O₃).

Referring to FIG. 1B, a first insulating layer 112 is formed in the first openings 105 and the second openings 115, and the resistance switching material 108 is divided into discontinuous resistance switching layers 108A, 108B, and 108C, and the first oxygen ion diffusion barrier material 110 is divided into discontinuous first oxygen ion diffusion barrier layers 110A, 110B, and 110C. The step of forming the first insulating layer 112 may include forming a first insulating material on the substrate 102 and filling the first openings 105 and the second openings 115. Next, a planarization process (e.g., a chemical mechanical polishing process) is performed to partially remove the first insulating material, the first oxygen ion diffusion barrier material 110, and the resistance switching material 108 on the sacrificial pattern layer 106 by using the sacrificial pattern layer 106 as a stop layer. The first insulating layer 112 may include suitable insulating materials, such as nitride, oxide, or oxynitride. In some embodiments, the first insulating layer 112 is black diamond. The first insulating layer 112 may be formed by chemical vapor deposition, atomic layer deposition, spin coating, or any other suitable deposition process.

Referring to FIG. 1C, a first etching process is performed to remove the sacrificial pattern layer 106 and form third openings 125. The third openings 125 expose sidewalls of the resistance switching layers 108A, 108B, 108C. The first etching process may include a wet etching process, a dry etching process, or a combination thereof. In order to completely remove the sacrificial pattern layer 106 and avoid damage to the resistance switching material 108, the first oxygen ion diffusion barrier material 110, and the first insulating layer 112, the etching rate of the sacrificial pattern layer 106 may be greater than the etching rate of the resistance switching material 108, the etching rate of the first oxygen ion diffusion barrier material 110, and the etching rate of the first insulating layer 112 during the first etching process. Furthermore, the material of the sacrificial pattern layer 106 may be different from the material of the first insulating layer 112. In some embodiments, in the first etching process, the ratio R1a/R1b of the etching rate R1a of the sacrificial pattern layer 106 to the etching rate R1b of the resistance switching material 108 is 3.0-20.0, and the ratio R1a/R1c of the etching rate R1a of the sacrificial pattern layer 106 to the etching rate R1c of the first oxygen ion diffusion barrier material 110 is 3.0-20.0.

Referring to FIG. 1D, the second oxygen ion diffusion barrier layer 114 is conformally formed in the third openings 125. In this embodiment, the second oxygen ion diffusion barrier layer 114 formed in the third openings 125 has a U-shaped cross-sectional profile. In this embodiment, each second oxygen ion diffusion barrier layer 114 is formed between adjacent ones of the resistance switching layers 108A, 108B, 108C, so that the inner and outer sidewalls of the resistance switching layers 108A, 108B, and 108C may be covered by the oxygen ion diffusion barrier material (i.e., the first oxygen ion diffusion barrier layers 110A, 110B, 110C or the second oxygen ion diffusion barrier layer 114), which is beneficial to increase the yield and reliability of the RRAM 100. The material of the second oxygen ion diffusion barrier layer 114 may be the same as or similar to the first oxygen ion diffusion barrier material 110.

Referring to FIG. 1E, a second insulating layer 116 that fills the third openings 125 is formed on the second oxygen ion diffusion barrier layer 114. In this embodiment, the second oxygen ion diffusion barrier layer 114 and the second insulating layer 116 may be planarized independently or simultaneously, so that the top surface of the second insulating layer 116, the top surface of the second oxygen ion diffusion barrier layer 114, the top surface of the first insulating layer 112, the top surfaces of the first oxygen ion diffusion barrier layers 110A, 110B, 110C, and the top surfaces of the resistance switching layers 108A, 108B, and 108C are coplanar. The material of the second insulating layer 116 may be the same as or similar to the material of the first insulating layer 112.

Moreover, in order to reduce the stress between the resistance switching material 108 and the oxygen ion diffusion barrier material (e.g., the material of the first oxygen ion diffusion barrier layers 110A, 110B, 110C or the material of the second oxygen ion diffusion barrier layer 114), the material of the second insulating layer 116 may be different from that of the sacrificial pattern layer 106. In this embodiment, the second insulating layer 116 is black diamond. In other embodiments, the second insulating layer 116 is made of oxide and is different from the material of the first insulating layer 112.

Referring to FIG. 1F, a third oxygen ion diffusion barrier material 118, an oxygen ion storage material 120, a fourth oxygen ion diffusion barrier material 122, and a top electrode material 124 are sequentially formed on the substrate 102.

The third oxygen ion diffusion barrier material 118 may be used to reduce or avoid vertical movement of oxygen ions. More specifically, in the high resistance state, the third oxygen ion diffusion barrier material 118 may prevent oxygen ions from diffusing into the oxygen ion storage material 120 from the resistance switching layers 108A, 108B, and 108C, so as to maintain the stability of the high resistance state. On the other hand, in the low resistance state, the third oxygen ion diffusion barrier material 118 may prevent oxygen ions from diffusing into the resistance switching layers 108A, 108B, and 108C from the oxygen ion storage material 120, so as to maintain the stability of the low resistance state. In order to block the vertical movement of oxygen ions, the third oxygen ion diffusion barrier material 118 may be different from the resistance switching material 108. The third oxygen ion diffusion barrier material 118 may be the same as or similar to the first oxygen ion diffusion barrier material 110.

When a forming voltage or a writing voltage is applied to the RRAM 100, the oxygen ion storage material 120 may be used to store oxygen ions from the resistance switching layers 108A, 108B, and 108C. When an erase voltage is applied to the RRAM 100, the oxygen ions stored in the oxygen ion storage material 120 may be driven back into the resistance switching layers 108A, 108B, and 108C. The oxygen ion storage material 120 may include titanium (Ti), tantalum (Ta), hafnium (Hf), or zirconium (Zr). In some embodiments, the material of the oxygen ion storage material 120 is titanium.

The fourth oxygen ion diffusion barrier material 122 may be used to reduce or avoid vertical movement of oxygen ions. More specifically, in the low resistance state, the fourth oxygen ion diffusion barrier material 122 may prevent oxygen ions from diffusing into the top electrode material 124 from the oxygen ion storage material 120. Therefore, oxidation of the top electrode material 124 may be avoided, thereby improving the performance and yield of the memory device. The fourth oxygen ion diffusion barrier material 122 may be the same as or similar to the first oxygen ion diffusion barrier material 110.

The top electrode material 124 may include titanium, tantalum, titanium nitride, tantalum nitride, other suitable conductive materials, or a combination thereof. In some embodiments, the bottom electrode material 104 is titanium and the top electrode material 124 is titanium nitride. In other embodiments, the bottom electrode material 104 is titanium nitride and the top electrode material 124 is titanium.

Referring to FIG. 1G, a patterning process is performed to form memory cells on the substrate 102. Next, an insulating structure 130 is formed between two adjacent memory cells. Specifically, a suitable dry etching process (e.g., a plasma etching process) may be performed to form openings (or trenches) through the bottom electrode material 104, resistance switching material 108 (e.g., a portion of the resistance switching layers 108A and 108C), the first oxygen ion diffusion barrier material 110 (e.g., a portion of the first oxygen ion diffusion barrier layers 110A and 110C), the first insulating layer 112, the third oxygen ion diffusion barrier material 118, the oxygen ion storage material 120, the fourth oxygen ion diffusion barrier material 122, and the top electrode material 124 at the interface between the different regions (e.g., the first region 10 and the second region 20). A bottom electrode layer 104′, a third oxygen ion diffusion barrier layer 118′, an oxygen ion storage layer 120′, a fourth oxygen ion diffusion barrier layer 122′ and a top electrode layer 124′ are formed. Next, the insulating material is filled into the openings. Next, a planarization process is performed to remove excess insulating material on the top electrode layer 124′ to form the insulating structure 130. The material and formation method of the insulating structure 130 may be the same as or similar to the material and formation method of the first insulating layer 112.

In this embodiment, the resistance switching material 108 in the second opening 115 is patterned to form two mirror-symmetrical L-shaped structures (i.e., the L-shaped resistance switching layer 108C in the first region 10 and the L-shaped resistance switching layer 108A in the second region 20). Similarly, the first oxygen ion diffusion barrier material 110 in the second opening 115 is also patterned to form two mirror-symmetrical L-shaped structures (i.e., the L-shaped first oxygen ion diffusion barrier layer 110C in the first region 10 and the L-shaped first oxygen ion diffusion barrier layer 110A in the second region 20).

Afterwards, other conventional processes (e.g., a contact structure may be formed on the top electrode layer 124′) may be performed to complete the RRAM 100, which will not be described in detail here.

Referring to FIG. 1G, in some embodiments, the RRAM 100 includes bottom contact structures 101 formed in the substrate 102, memory cells formed on the substrate 102, and an insulating structure 130 formed between two adjacent memory cells. Each memory cell is in the first region 10 or the second region 20, and includes the bottom electrode layer 104′, the resistance switching layer (e.g., 108A, 108B, and 108C), the first oxygen ion diffusion barrier layer (e.g., 110A, 110B, and 110C), the third oxygen ion diffusion barrier layer 118′, the oxygen ion storage layer 120′, the fourth oxygen ion diffusion barrier layer 122′, and the top electrode layer 124′ sequentially formed on the substrate 102. Moreover, each memory cell further includes U-shaped second oxygen ion diffusion barrier layers 114 disposed between the adjacent resistance switching layers 108A, 108B, and 108C. By applying voltages to the bottom electrode layer 104′ and the top electrode layer 124′, the resistance switching layers 108A, 108B, 108C may be converted to different resistance states.

In this embodiment, the resistance switching layer 108A and the resistance switching layer 108C are L-shaped, and the resistance switching layer 108B is U-shaped. The U-shaped resistance switching layer 108B includes two vertical portions and one horizontal portion. The L-shaped resistance switching layer 108A or 108C includes one vertical portion and one horizontal portion. In the first region 10, the horizontal portion of the resistance switching layer 108A extends from its vertical portion in a direction away from the center of the memory cell, and the horizontal portion of the resistance switching layer 108C extends from its vertical portion in a direction away from the center of the memory cell. That is, the horizontal portions of the resistance switching layer 108A and the resistance switching layer 108C are on opposite sides of the vertical portions thereof, respectively. In other words, the resistance switching layer 108A and the resistance switching layer 108C in the same memory cell are arranged horizontally in a back-to-back manner.

In some embodiments, the length of the horizontal portion of the resistance switching layer 108A is different from the length of the horizontal portion of the resistance switching layer 108C. In other embodiments, the length of the horizontal portion of the resistance switching layer 108A is the same as the length of the horizontal portion of the resistance switching layer 108C. That is, the resistance switching layer 108A and the resistance switching layer 108C are mirror-symmetrical to each other.

In this embodiment, the first oxygen ion diffusion barrier layers 110A and 110C are L-shaped, and the first oxygen ion diffusion barrier layer 110B is U-shaped. The first oxygen ion diffusion barrier layer 110A is formed on the trench formed by the resistance switching layer 108A, the first oxygen ion diffusion barrier layer 110B is formed on the trench formed by the resistance switching layer 108B, and the first oxygen ion diffusion barrier layer 110C is formed on the trench formed by the resistance switching layer 108C. The first oxygen ion diffusion barrier layers (110A, 110B, 110C) and the second oxygen ion diffusion barrier layers 114 are respectively formed on the inner and outer sidewalls of the vertical portions of the resistance switching layers 108A, 108B, 108C.

The bottom electrode layer 104′ is formed on one of the bottom contact structures 101. In this embodiment, there are one resistance switching layer 108A with an L-shaped cross-section, two resistance switching layers 108B with a U-shaped cross-section, one resistance switching layer 108C with an L-shaped cross-sectional profile, and a plurality of second oxygen ion diffusion barrier layers 114 with a U-shaped cross-sectional profile between the top electrode layer 124′ and the bottom electrode layer 104′. More specifically, the resistance switching layers 108A, 108B, 108C, the first oxygen ion diffusion barrier layers 110A, 110B, 110C and the second oxygen ion diffusion barrier layer 114 are disposed in the overlapping area of the vertical projection of the top electrode layer 124′ and the vertical projection of the bottom electrode layer 104′.

In the manufacturing method of the RRAM 100 provided in this embodiment, by controlling the shape and size of the resistance switching layer, the position and shape of the conductive path may be effectively controlled, thereby improving the reliability and performance uniformity of the memory device.

In more detail, referring to FIG. 1G, when voltage is applied, the resistance switching layers 108A, 108B, and 108C of the present embodiment may confine the conductive path to the vertical portion of each resistance switching layer 108A, 108B, and 108C, compared to the conventional planar resistance switching layers. In other words, by forming the resistance switching layers 108A, 108B, and 108C, the position and shape of the conductive paths may be effectively controlled. In this way, the reliability and performance uniformity of the RRAM 100 may be improved. In some embodiments, the top surface of the vertical portion of each resistance switching layer 108A, 108B, and 108C has a third width W3 (shown in FIG. 1E) between 5-20 Å.

On the other hand, in this embodiment, the inner and outer sidewalls of the vertical portions of each resistance switching layer 108A, 108B, and 108C are covered by the oxygen ion diffusion barrier layer. Therefore, when voltage is applied, the horizontal movement of oxygen ions may be greatly reduced or avoided, and oxygen ions from the insulating layers (i.e., the first insulating layer 112 and the second insulating layer 116) may be prevented from entering the resistance switching layer to affect the number and size of conductive paths. In other words, with the resistance switching layers 108A, 108B, and 108C, the first oxygen ion diffusion barrier layers 110A, 110B, and 110C, and the second oxygen ion diffusion barrier layer 114 in this embodiment, it is easier to predict and control the resistance value of the high resistance state and the low resistance state. In this way, low resistance state degrade or high resistance state degrade may be avoided, and the yield and reliability of the RRAM 100 may be improved.

In order to prevent oxygen ions from entering or leaving the vertical portions of the resistance switching layers 108A, 108B and, 108C horizontally, referring to FIG. 1E, in some embodiments, the top surfaces of the vertical portions of the first oxygen ion diffusion barrier layers 110A, 110B, and 110C all have a fourth width W4, and the fourth width W4 is 10-50 nm. The top surface of the vertical portion of the second oxygen ion diffusion barrier layer 114 has a fifth width W5, and the fifth width W5 is 10-50 nm. In other embodiments, materials with stronger oxygen ion blocking ability may be selected to form the first oxygen ion diffusion barrier layers 110A, 110B, and 110C and the second oxygen ion diffusion barrier layer 114, so that the fourth width W4 and the fifth width W5 may be reduced, which is beneficial to the miniaturization of the RRAM 100.

Referring to FIG. 1F, in this embodiment, compared with the thicknesses of the vertical portions of the first oxygen ion diffusion barrier layers 110A, 110B, and 110C and the second oxygen ion diffusion barrier layer 114, the third oxygen ion diffusion barrier material 118 and the fourth oxygen ion diffusion barrier material 122 may have smaller thicknesses. This will facilitate the movement (i.e., vertical movement) of oxygen ions between the oxygen ion storage layer 120′ and the resistance switching layers 108A, 108B, and 108C. On the other hand, in order to further avoid unintended diffusion of oxygen ions, the third oxygen ion diffusion barrier material 118 may have a first thickness T1 between 1-5 nm, and the fourth oxygen ion diffusion barrier material 122 may have a second thickness T2 of 1-5 nm.

In other embodiments, more first openings 105 may be formed in the first region 10, so that the memory cells in the first region 10 may have more U-shaped resistance switching layers 108B. Thus, the area available for forming conductive paths will be increased. In this way, the performance and yield of the RRAM 100 may be further improved.

Referring to FIG. 1G, the top surfaces of the resistance switching layers 108A, 108B, and 108C are coplanar, and the bottom surfaces of the resistance switching layers 108A, 108B, and 108C are coplanar. Since each of the resistance switching layers 108A, 108B, and 108C includes a horizontal portion electrically connected to the bottom electrode layer 104′ may store a portion of oxygen ions, when the erase voltage is applied, some oxygen ions may enter the vertical portion from the horizontal portion of the resistance switching layers 108A, 108B and 108C. Therefore, it is easier to recombine all oxygen vacancies with oxygen ions. In this way, the reset efficiency may be improved, and the performance of the RRAM 100 may be further improved.

Referring to FIG. 1A, in this embodiment, since the second opening 115 has the second width W2 greater than the first width W1, after the insulating structure 130 is formed, the L-shaped resistance switching layer 108C in the first region 10 and the L-shaped resistance switching layer 108A in the second region 20 may still retain horizontal portions with appropriate lengths to store oxygen ions. It should be understood that the number and size of the first opening 105 and the second opening 115 shown in FIG. 1A are only for illustration, and are not intended to limit the present invention.

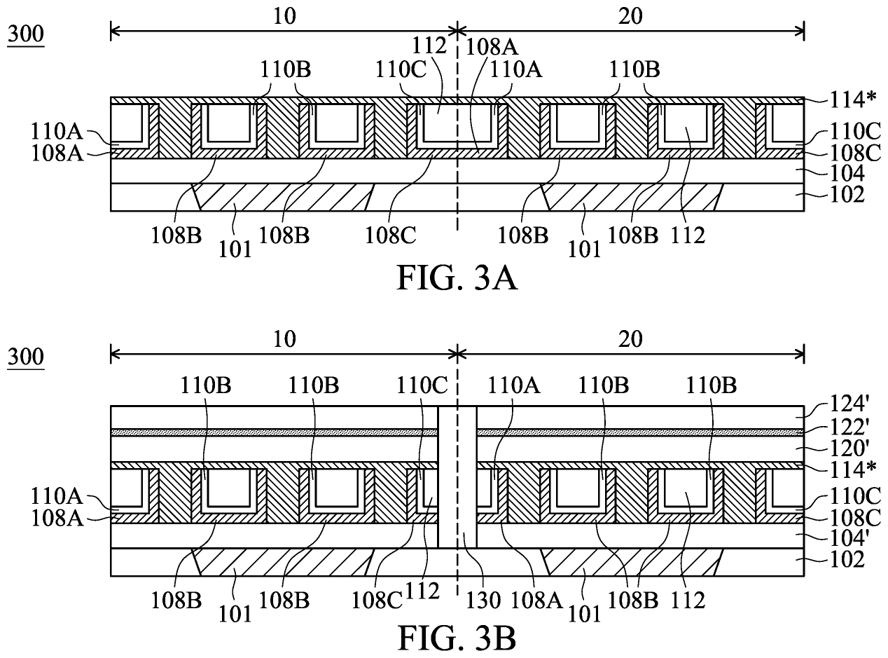

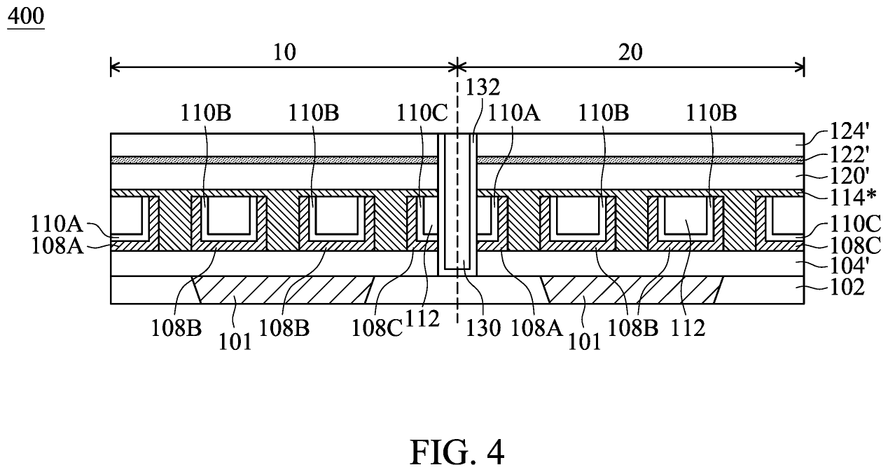

Referring to FIG. 1A, an included angle θ1 is between the bottom and the sidewall of the sacrificial pattern layer 106. Since the resistance switching material 108 and the first oxygen ion diffusion barrier material 110 are conformally formed on the sacrificial pattern layer 106, an included angle θ2 between the bottoms and the sidewalls of the first opening 105 and the second opening 115 is substantially complementary to the included angle θ1. In order to facilitate filling of the first insulating layer 112 in the first openings 105 and the second openings 115, the included angle θ2 is 75 degrees to 105 degrees in some embodiments. Furthermore, referring to FIG. 1C, since the position and shape of the third opening 125 corresponds to the sacrificial pattern layer 106, there is an included angle θ1 between the bottom and the sidewall of the third opening 125. In order to facilitate filling of the second insulating layer 116, the second oxygen ion diffusion barrier layer 114 or the second oxygen ion diffusion barrier layer 114* (shown in FIG. 3B and FIG. 4) in the third opening 125, the included angle θ2 is 75 degrees to 105 degrees. Referring to FIG. 1A, in this embodiment, the sidewall of the sacrificial pattern layer 106 are substantially perpendicular to the surface of the bottom electrode material 104. In other words, the included angle θ1 and the included angle θ2 are both about 90 degrees.

It should be noted that in this specification, the “L-shaped” may include “L-shaped” and “L-like”, and the “U-shaped” may include “U-shaped” and “U-like”. In other words, when the included angle θ1 is 75 degrees to 105 degrees, the formed resistance switching layers 108A, 108C and the first oxygen ion diffusion barrier layers 110A and 110C may be regarded as having an “L-shaped” cross-sectional profile. Similarly, when the included angle θ2 is 75 degrees to 105 degrees, the formed resistance switching layer 108B, the first oxygen ion diffusion barrier layer 110B and the second oxygen ion diffusion barrier layer 114 may be regarded as having a “U-shaped” cross-sectional profile.

In this embodiment, not by an etching process (e.g., a plasma etching process), but by a planarization process to remove the second insulating layer 116 and expose the top surfaces of the resistance switching layers 108A, 108B, 108C. This prevents the top surfaces of the resistance switching layers 108A, 108B, 108C from being damaged during the etching process. Therefore, the performance and yield of the RRAM 100 may be further improved.

The RRAM 200 shown in FIG. 2 is similar to the RRAM 100 shown in FIG. 1G, except that the RRAM 200 shown in FIG. 2 further includes a fifth oxygen ion diffusion barrier layer 132. In order to simplify the description, the same components and their process steps as shown in FIG. 1G will not be described in detail here.

Referring to FIG. 2, the fifth oxygen ion diffusion barrier layer 132 has a U-shaped cross-sectional profile, and the insulating structure 130 fills the trench formed by the fifth oxygen ion diffusion barrier layer 132. In the process as shown in FIG. 1G, after openings or trenches are formed at the interface between different regions (e.g., the first region 10 and the second region 20), the oxygen ion diffusion barrier material may be conformably formed on the memory cell. Next, the insulating material is filled into the openings or trenches. Next, a planarization process is performed to remove excess insulating material and oxygen ion diffusion barrier material on the top electrode layer 124′, so as to form the insulating structure 130 and the fifth oxygen ion diffusion barrier layer 132. The material and thickness of the fifth oxygen ion diffusion barrier layer 132 may be the same as or similar to the material and thickness of the first oxygen ion diffusion barrier material 110.

In the first region 10, the fifth oxygen ion diffusion barrier layer 132 is formed between the horizontal portion of the resistance switching layer 108C and the insulating structure 130. In the second region 20, the fifth oxygen ion diffusion barrier layer 132 is formed between the horizontal portion of the resistance switching layer 108A and the insulating structure 130. The fifth oxygen ion diffusion barrier layer 132 may prevent oxygen ions from diffusing into the resistance switching layer 108C in the first region 10 and the resistance switching layer 108A in the second region 20 from the insulating structure 130. Therefore, the performance and yield of the RRAM 200 may be further improved.

FIG. 3A and FIG. 3B are similar to FIG. 1D and FIG. 1G, respectively. The RRAM 300 shown in FIG. 3B is similar to the RRAM 100 shown in FIG. 1G, except that the cross-sectional profile of the second oxygen ion diffusion barrier layer 114* in FIG. 3B is different from the cross-sectional profile of the second oxygen ion diffusion barrier layer 114 in FIG. 1G. In order to simplify the description, the same components, process steps and advantages as those shown in FIG. 1G will not be described in detail here.

The position of the top surface of the second oxygen ion diffusion barrier layer 114* may be controlled by adjusting the duration of the planarization process. As shown in FIG. 3A, after the planarization process, the top surface of the second oxygen ion diffusion barrier layer 114* is higher than the top surface of the first insulating layer 112, the top surfaces of the first oxygen ion diffusion barrier layers 110A, 110B, 110C, and the top surfaces of the resistance switching layers 108A, 108B, 108C. The material of the second oxygen ion diffusion barrier layer 114* may be the same as or similar to the material of the second oxygen ion diffusion barrier layer 114.

In this embodiment, the second oxygen ion diffusion barrier layer 114* is formed to completely fill the third opening 125. The thermal conductivity of the second oxygen ion diffusion barrier layer 114* is better than that of the second insulating layer 116. Therefore, the heat dissipation capability of the memory unit may be improved, thereby enhancing the performance of the RRAM 300. Furthermore, in this embodiment, the forming step and the planarizing step of the second insulating layer 116 may be omitted. Therefore, the manufacturing method provided in this embodiment may simplify the manufacturing process and reduce the time and cost required for production.

The RRAM 400 shown in FIG. 4 is similar to the RRAM 300 shown in FIG. 3B except that the RRAM 400 shown in FIG. 4 further includes the fifth oxygen ion diffusion barrier layer 132. In order to simplify the description, the same components, process steps and advantages as those shown in FIG. 3B will not be described in detail here.

By forming the fifth oxygen ion diffusion barrier layer 132, oxygen ions may be prevented from diffusing into the L-shaped resistance switching layer 108C in the first region 10 and the L-shaped resistance switching layer 108A in the second region 20 from the insulating structure 130. Therefore, the performance and yield of the RRAM 400 may be further improved.

In summary, in the RRAM manufacturing method provided by the embodiment of the present invention, by forming the sacrificial pattern layer, L-shaped resistance switching layers and U-shaped resistance switching layers may be formed between the top electrode layer and the bottom electrode layer of the same memory cell. The vertical portions of the L-shaped resistance switching layer and the U-shaped resistance switching layer may effectively control the position and shape of the conductive path. In this way, the reliability and performance uniformity of the RRAM can be improved.

Furthermore, the horizontal portions of the L-shaped resistance switching layer and the U-shaped resistance switching layer may store a portion of oxygen ions. In this way, the reset efficiency may be improved, and the performance of the RRAM may be further improved. In the RRAM manufacturing method provided by the embodiment of the present invention, by controlling the shape and size of the sacrificial pattern layer and the process conditions for depositing the resistance switching layer, the quantity and size of the resistance switching layer with a specific shape may be controlled. Therefore, the flexibility of the process is high.

Moreover, in the RRAM provided by the embodiments of the present invention, oxygen ion diffusion barrier layers are provided on the inner and outer sidewalls of the vertical portion of the resistance switching layer, which may confine the horizontal movement of oxygen ions in the resistance switching layer. Therefore, the occurrence of low-resistance state degrade or high-resistance state degrade may be avoided. In this way, the yield and reliability of the RRAM may be improved. In addition, the manufacturing method provided by the embodiment of the present invention may be easily integrated into the existing RRAM manufacturing process.

While the invention has been described by way of example and in terms of the preferred embodiments, the invention is not limited to the disclosed embodiments. Anyone skilled in the technical field can make any changes and modifications without departing from the spirit and scope of the present invention. Therefore, the scope of the present invention should be determined by the scope of the claims.

What is claimed is:

1. A resistive random access memory, comprising:
bottom contact structures formed in a substrate;
memory cells formed on the substrate, wherein each of the memory cells comprises:
a bottom electrode layer formed on one of the bottom contact structures;
two L-shaped resistance switching layers formed on the bottom electrode layer, wherein each of the L-shaped resistance switching layers has a horizontal portion and a vertical portion;
oxygen ion diffusion barrier layers formed on inner and outer sidewalls of the vertical portion of each of the L-shaped resistance switching layers; and
a top electrode layer, wherein the L-shaped resistance switching layers and the oxygen ion diffusion barrier layers are between the top electrode layer and the bottom electrode layer; and
an insulating structure formed between adjacent two of the memory cells.

2. The resistive random access memory as claimed in claim 1, wherein in each of the memory cells, the horizontal portion of each of the L-shaped resistance switching layers extends from the vertical portion of each of the L-shaped resistance switching layers in a direction away from a center of the memory cell.

3. The resistive random access memory as claimed in claim 1, wherein each of the memory cells further comprises:
at least one U-shaped resistance switching layer formed on the bottom electrode layer and between the L-shaped resistance switching layers, wherein the U-shaped resistance switching layer is between the top electrode layer and the bottom electrode layer.

4. The resistive random access memory as claimed in claim 3, wherein a top surface of the U-shaped resistance switching layer and a top surface of the L-shaped resistance switching layers are coplanar, and a bottom surface of the U-shaped resistance switching layer and a bottom surface of the L-shaped resistance switching layers are coplanar.

5. The resistive random access memory as claimed in claim 3, wherein the U-shaped resistance switching layer has two vertical portions and one horizontal portion, and the oxygen ion diffusion barrier layers are also formed on inner and outer sidewalls of the vertical portions of the U-shaped resistance switching layer.

6. The resistive random access memory as claimed in claim 3, wherein in each of the memory cells, one of the oxygen ion diffusion barrier layers that is between one of the L-shaped resistance switching layers and the U-shaped resistance switching layer has a U-shaped profile.

7. The resistive random access memory as claimed in claim 5, wherein a space between one of the L-shaped resistance switching layers and the U-shaped resistance switching layer is completely filled with the oxygen ion diffusion barrier layer.

8. The resistive random access memory as claimed in claim 1, further comprising:
a U-shaped oxygen ion diffusion barrier layer, wherein the insulating structure fills a trench formed by the U-shaped oxygen ion diffusion barrier layer.

9. The resistive random access memory as claimed in claim 1, wherein a top surface of the vertical portion of each of the L-shaped resistance switching layers has a width of 5-20 Å.

10. The resistive random access memory as claimed in claim 1, wherein a top surface of one of the oxygen ion diffusion barrier layers that is formed on sidewalls of the vertical portions of the L-shaped resistance switching layers has a first width, and the first width is 10-50 nm.

11. The resistive random access memory as claimed in claim 1, further comprising:
a third oxygen ion diffusion barrier layer formed on the oxygen ion diffusion barrier layers and the L-shaped resistance switching layers;
an oxygen ion storage layer formed on the third oxygen ion diffusion barrier layer; and
a fourth oxygen ion diffusion barrier layer formed on the oxygen ion storage layer,
wherein the top electrode layer is formed on the fourth oxygen ion diffusion barrier layer.

12. A manufacturing method of a resistive random access memory, comprising:
forming bottom contact structures in a substrate;
forming a bottom electrode material on the substrate;
forming a sacrificial pattern layer on the bottom electrode material, wherein the sacrificial pattern layer comprises first openings;
conformally forming a resistance switching material on the sacrificial pattern layer;
conformally forming a first oxygen ion diffusion barrier material on the resistance switching material;
performing a first planarization process to make sure a top surface of the first oxygen ion diffusion barrier material, a top surface of the resistance switching material and a top surface of the sacrificial pattern layer are coplanar;
removing the sacrificial pattern layer to form second openings, wherein the second openings expose sidewalls of the resistance switching material;
forming a second oxygen ion diffusion barrier layer on the sidewalls of the resistance switching material;
forming a top electrode material on the resistance switching material, the first oxygen ion diffusion barrier material, and the second oxygen ion diffusion barrier layer;
performing a patterning process to form an opening of insulating structure through the bottom electrode material, the resistance switching material, the first oxygen ion diffusion barrier material, and the top electrode material to define memory cells on the substrate; and
forming an insulating structure in the opening of insulating structure.

13. The manufacturing method of the resistive random access memory as claimed in claim 12, wherein each of the memory cells comprises:
a bottom electrode layer formed on one of the bottom contact structures;
two L-shaped resistance switching layers formed on the bottom electrode layer, wherein each of the L-shaped resistance switching layers has a horizontal portion and a vertical portion;
oxygen ion diffusion barrier layers formed on inner and outer sidewalls of the vertical portion of each of the L-shaped resistance switching layers; and
a top electrode layer, wherein the L-shaped resistance switching layers and the oxygen ion diffusion barrier layers are between the top electrode layer and the bottom electrode layer.

14. The manufacturing method of the resistive random access memory as claimed in claim 12, wherein forming a second oxygen ion diffusion barrier layer comprises:
conformally forming the second oxygen ion diffusion barrier layer on the resistance switching material and in the second openings.

15. The manufacturing method of the resistive random access memory as claimed in claim 14, further comprising:
after forming the first oxygen ion diffusion barrier material, forming a first insulating material to fill the first openings;
after forming the second oxygen ion diffusion barrier layer, forming a second insulating material to fill the second openings; and
performing a second planarization process to make sure the top surface of the first oxygen ion diffusion barrier material, a top surface of the second oxygen ion diffusion barrier layer, the top surface of the resistance switching material, a top surface of the first insulating material, and a top surface of the second insulating material are coplanar.

16. The manufacturing method of the resistive random access memory as claimed in claim 15, wherein a material of the sacrificial pattern layer is different from the first insulating material, and a material of the sacrificial pattern layer is different from the second insulating material.

17. The manufacturing method of the resistive random access memory as claimed in claim 12, wherein forming the second oxygen ion diffusion barrier layer comprises:
forming the second oxygen ion diffusion barrier layer to completely fill the second openings.

18. The manufacturing method of the resistive random access memory as claimed in claim 17, further comprising:
after forming the first oxygen ion diffusion barrier material, forming a first insulating material to fill the first openings; and
performing a second planarization process to planarize a top surface of the second oxygen ion diffusion barrier layer, wherein after the second planarization process, the top surface of the second oxygen ion diffusion barrier layer is higher than the top surface of the first oxygen ion diffusion barrier material and the top surface of the resistance switching material.
